(19) United States
(12) Patent Application Publication
(10) Pub. No.: US 2008/0067638 A1
(43) Pub. Date: Mar. 20, 2008

(54) Chip-scale packaging leadframe for memory chip

(75) Inventors: Hung-Li Chang, Hsi-Chi (TW); Jack C. Huang, Hsi-Chi (TW); Clement Ho, Hsi-Chi (TW)

Correspondence Address: BIRCH STEWART KOLASCH & BIRCH, PO BOX 747, FALLS CHURCH, VA, 22040-0747, US

(73) Assignee: Title Max Technology Co., Ltd.

(21) Appl. No.: 11/522,446

(22) Filed: Sep. 18, 2006

(51) Int. Cl. H01L 23/495

(52) U.S. Cl. 257/666

(57) ABSTRACT

A chip-scale packaging leadframe for a memory chip is provided, where the external leads of at least a pair of the V_{DD} leads and at least a pair of the V_{SS} leads are arranged on two parallel and opposing sides, namely, the first side and the third side, respectively, while all or almost all external leads of the other leads are arranged on the other two parallel and opposing sides, namely, the second side and the fourth side, respectively. According to the present invention, the dimension of the external leads of the V_{DD} and V_{SS} leads should be at least 0.4×1.15 mm; or the area of the external leads of the V_{DD} and V_{SS} leads should be at least 1.8 times of that of the other leads. Also according to the present invention, the gap of the external leads of adjacent V_{DD} and V_{SS} leads should be at least 1.0 mm; or at least two times of that of the other leads.

### BACKGROUND OF THE INVENTION

1. Field of the Invention

The present invention generally relates to leadframes, and more particularly to a leadframe for packaging a memory chip in a chip-scale package.

2. The Prior Arts

Driven by the continuous demand for even smaller and lighter electronic devices, the so-called chip-scale package (CSP) of a chip where the dimension of the package is less than 1.2 times of that of the chip and the package is directly surface mountable according to the definition of the Electronic Industries Association (EIA), is widely adopted by the semiconductor packaging industry.

There are various styles of CSPs and, among them, the so-called leadframe-based CSP uses the leadframe as the support to the chip. The leadframe-based CSP is ideal for chips of high operation frequency (above 400 MHz) and low pin count (below 100), such as the communication chip for mobile phones, digital signal processing chips, and memory chips. Additionally, the process and material used by the leadframe-based CSP is very similar or identical to those of the conventional packaging methods and, therefore, the leadframe-based CSP enjoys superior yield and production cost.

As the computational speed of the CPU is continuously increased, the processing speed of the memory chip has to be increased as well. Under this trend, the conventional leadframe used in chip-scale packaging (hereinafter, CSP leadframe) has a number disadvantages. First of all, in the conventional CSP leadframe, the V_{DD} lead for power supply and the V_{SS} lead for ground are no different from the other leads. Usually, the external leads of the V_{DD} lead, the V_{SS} lead, and the other leads are together arranged along two opposing sides of the CSP leadframe and the gaps between any two adjacent external leads are all identical. In this way, a short circuit could be developed between the other leads to the V_{DD} lead or the V_{SS} lead if caution is not exercised during the packaging process, thereby causing a reduced yield.

In addition, if a memory chip is clocked at a higher frequency, the memory chip would consume a larger power. But for the conventional CSP leadframe, the pitches of the internal leads of the V_{DD} lead and the V_{SS} lead are no different from those of the other leads. Similarly, the pad areas of the external leads of the V_{DD} lead and the V_{SS} lead are also identical to those of the other leads. These imply that the memory chip packaged using the conventional CSP leadframe is limited in terms its power consumption. In other words, to drive the memory chip to run at an even higher speed, the V_{DD} lead and the V_{SS} lead of the CSP leadframe have to be designed differently and more effectively.

### SUMMARY OF THE INVENTION

Accordingly, the present invention provides a CSP leadframe for a memory chip which can deliver the higher power required by the high-speed memory chip and can help improving the yield of the packaging process.

A major feature of the CSP leadframe is that the external leads of at least a pair of the V_{DD} leads and at least a pair of the V_{SS} leads are arranged on two parallel and opposing sides, namely, the first side and the third side, respectively, while all or almost all external leads of the other leads are arranged on the other two parallel and opposing sides, namely, the second side and the fourth side, respectively. These first, second, third, and fourth sides are derived by numbering the sides of the CSP leadframe in a clockwise manner. By separately positioning the V_{DD} leads and the V_{SS} leads away from the other leads, the gaps and pad areas of the V_{DD} leads and the V_{SS} leads could be designed to fit the needs of high-speed memory chip. According to the present invention, the dimension of the external leads of the V_{DD} and V_{SS} leads should be at least 0.4×1.15 mm; or the area of the external leads of the V_{DD} and V_{SS} leads should be at least 1.8 times of that of the other leads. Also according to the present invention, the gap of the external leads of adjacent V_{DD} and V_{SS} leads should be at least 1.0 mm; or at least two times of that of the other leads.

The internal leads of the pair of the V_{DD} leads are connected with each other to form a linear segment perpendicular to the first and third sides of the CSP leadframe. Similarly, the internal leads of the pair of the V_{SS} leads are connected with each other to form another linear segment perpendicular to the first and third sides of the CSP leadframe. The internal leads of the other leads are located between the two linear segments and the second and fourth sides of the CSP leadframe, respectively.

The CSP leadframe can further contains a third V_{DD} lead and a third V_{SS} lead whose external leads are positioned along the second and fourth sides of the CSP leadframe, respectively, and whose internal leads are connected to the linear segments of the pairs of the V_{DD} and V_{SS} leads respectively. The pitch of the third V_{DD} and V_{SS} leads is at least 2.5 times of those of the other leads.

The foregoing and other objects, features, aspects and advantages of the present invention will become better understood from a careful reading of a detailed description provided herein below with appropriate reference to the accompanying drawings.

### BRIEF DESCRIPTION OF THE DRAWINGS

FIG. 1 is a schematic top view showing the internal of a chip-scale packaged memory chip using a CSP leadframe according to an embodiment of the present invention.

FIG. 2 is a schematic bottom view showing the external of the chip-scale packaged memory chip of FIG. 1.

### DETAILED DESCRIPTION OF THE PREFERRED EMBODIMENTS

The following descriptions are exemplary embodiments only, and are not intended to limit the scope, applicability or configuration of the invention in any way. Rather, the following description provides a convenient illustration for implementing exemplary embodiments of the invention. Various changes to the described embodiments may be made in the function and arrangement of the elements described without departing from the scope of the invention as set forth in the appended claims.

A CSP leadframe for a memory chip is provided herein which can deliver the higher power required by the high-speed memory chip and can help improving the yield of the packaging process. Please note that the present invention does not place specific constraints on the packaging process, the specification or technology of the memory chip, and the style of the packaged product.

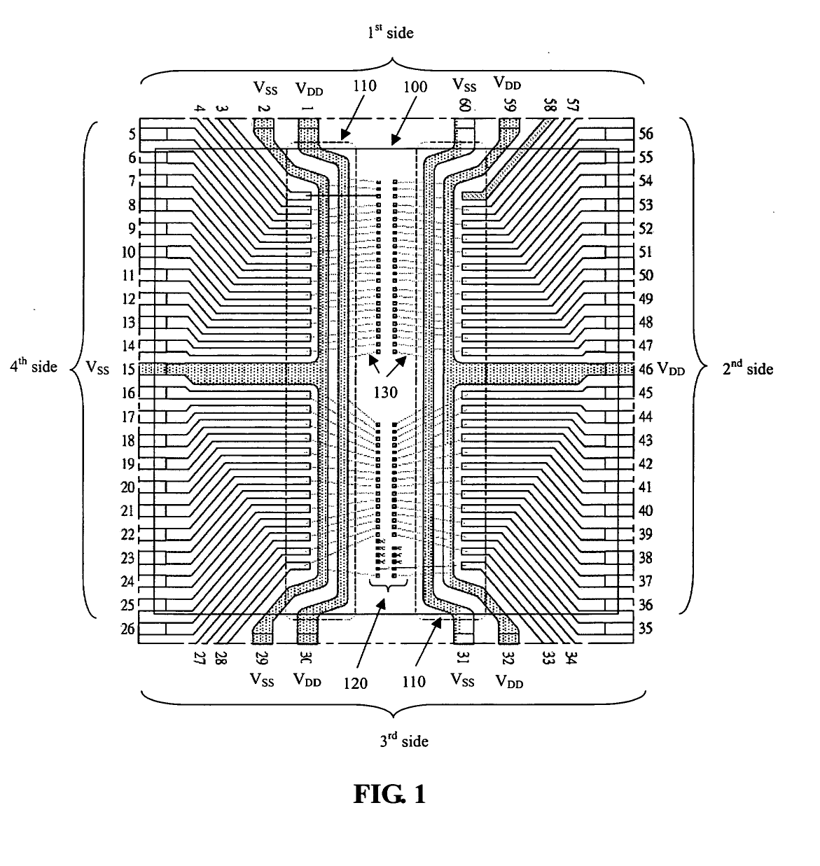

FIG. 1 is a schematic top view showing the internal of a chip-scale packaged memory chip using a CSP leadframe according to an embodiment of the present invention. For simplification, the memory chip (such as a 512M DDR II memory chip) 100 is represented by a solid box while he adhesive tapes 110 for attaching the memory chip 100 to the CSP leadframe is depicted as a dashed box in the drawing. The electrical connection between the bond pads 120 of the memory chip 100 and the appropriate leads of the CSP leadframe respectively are achieved by wire-bonding using the conductive wires 130. Please note that the CSP leadframe shown in the drawing contains 60 leads numbered from 1 to 60. However, this is only exemplary and the principles of the present invention can actually be applied to CSP leadframes of different lead counts.

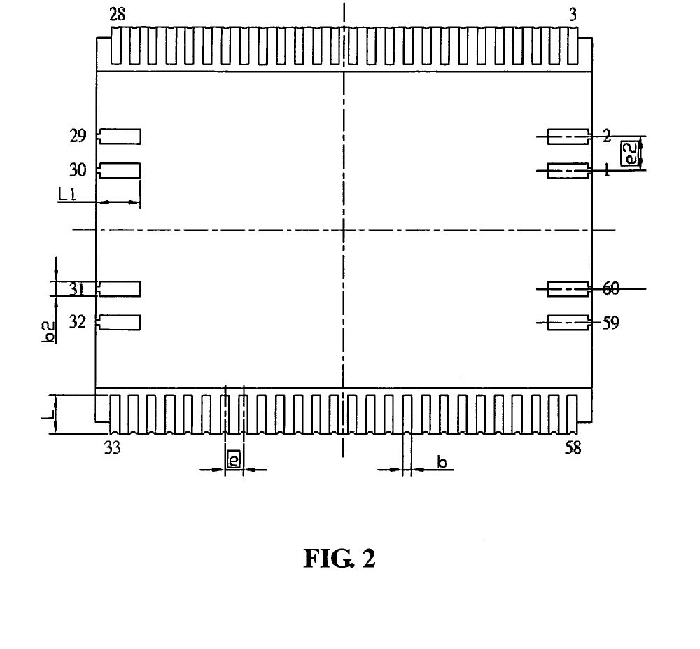

Each lead contains an internal lead which is the section wrapped inside the molding compound after packaging, and an external lead which is the other section exposed outside the molding compound. What is shown in FIG. 1 is the internal of the molding compound and the leads depicted are all internal leads of the leads 1˜60. The external leads can be seen from the bottom view of FIG. 2. As illustrated, the CSP leadframe of the present invention has a rectangular shape, just like a conventional leadframe, where two parallel and opposing sides are referred to as the first side and the third side, and the other two parallel and opposing sides are referred to as the second side and the fourth side (i.e., the four sides are numbered in a clockwise manner).

As shown in FIGS. 1 and 2, a major feature of the CSP leadframe is that the external leads of a pair of the V_{DD} leads 59 and 32 and a pair of the V_{SS} leads 2 and 29 are arranged on the parallel and opposing first and third sides, respectively, while all or almost all external leads of the other leads are arranged on the parallel and opposing second and fourth sides, respectively. Please note that, as shown in the drawings, the first and third sides can have additional V_{DD} leads 1 and 30, and additional V_{SS} leads 60 and 31. Please also note that it is not required that all external leads of the other leads are arranged on the parallel and opposing second and fourth sides. For example, the external lead of at least one of the other leads can be positioned along the rim of the leadframe between the pair of V_{DD} leads 59 and 32 and the second side. Similarly, it is possible to have the external lead of at least one of the other leads positioned along the rim of the leadframe between the pair of V_{SS} leads 2 and 29 and the fourth side.

As described, the present invention separately positions the V_{DD} leads and the V_{SS} leads away from the other leads, the gaps and pad areas of the V_{DD} leads and the V_{SS} leads therefore could be designed to fit the needs of high-speed memory chip. According to the present invention, the dimension of the external leads of the V_{DD} and V_{SS} leads should be at least 0.4×1.15 mm (i.e., b2≧0.4 mm, L1≧1.15 mm); or the area (L1×b2) of the external leads of the V_{DD} and V_{SS} leads should be at least 1.8 times of the area (L×b) of the other non-V_{DD} and non-V_{SS} leads. Also according to the present invention, the gap of the external leads of a V_{DD} lead and its adjacent lead along the first and third sides (e.g., the gap “e2” between the V_{DD} lead 59 and the adjacent lead 60) should be at least 1.0 mm; or at least two times of the gap “e” between the other non-V_{DD} and non-V_{SS} leads. Similarly, the gap of the external leads of a V_{SS} lead and its adjacent lead along the first and third sides (e.g., the gap “e2” between the V_{SS} lead 29 and the adjacent lead 30) should be at least 1.0 mm; or at least two times of the gap “e” between the other non-V_{DD} and non-V_{SS} leads.

The internal leads of the pair of V_{DD} leads 59 and 32 are connected with each other to form a linear segment perpendicular to the first and third sides and parallel to the neighboring second side of the CSP leadframe. Similarly, the internal leads of the pair of V_{DD} leads 1 and 30 are connected with each other to form a linear segment perpendicular to the first and third sides and parallel to the neighboring fourth side of the CSP leadframe. On the other hand, the internal leads of the pair of V_{SS} leads 2 and 29 are connected with each other to form a linear segment perpendicular to the first and third sides and parallel to the neighboring fourth side of the CSP leadframe. Similarly, the internal leads of the pair of V_{SS} leads 60 and 31 are connected with each other to form a linear segment perpendicular to the first and third sides and parallel to the neighboring second side of the CSP leadframe. In the mean time, the internal leads of the other non-V_{DD} and non-V_{SS} leads are located between these linear segments and the second and fourth sides of the CSP leadframe, respectively. These linear segments allow the CSP leadframe to deliver a significantly larger power as there is very few turns in these linear segments and their pitches can be appropriately enlarged.

In addition, as shown in FIG. 1, the CSP leadframe can further contains at least a third V_{DD} lead (e.g., lead 46) and at least a third V_{SS} lead (e.g., lead 15) whose external leads are positioned along the second and fourth sides of the CSP leadframe, respectively. The internal lead of the third V_{DD} lead is then connected to a linear segment between a pair of the V_{DD} leads on the first and third sides. Similarly, the internal lead of the third V_{SS} lead is connected to a linear segment between a pair of the V_{SS} leads on the first and third sides. According to the present invention, the pitches of these third V_{DD} and V_{SS} leads are at least 2.5 times of those of the other non-V_{DD} and non-V_{SS} leads so as to sustain more power consumption. However, as shown in FIG. 2, please note that the dimensions (or areas) and gaps of the external leads of these third V_{DD} and V_{SS} leads can be identical to those of the other non-V_{DD} and non-V_{SS} leads.

Although the present invention has been described with reference to the preferred embodiments, it will be understood that the invention is not limited to the details described thereof. Various substitutions and modifications have been suggested in the foregoing description, and others will occur to those of ordinary skill in the art. Therefore, all such substitutions and modifications are intended to be embraced within the scope of the invention as defined in the appended claims.

What is claimed is:

1. A chip-scale packaging leadframe for a memory chip, said leadframe having a first side, a second side, a third side parallel and opposing to said first side, and a fourth side parallel and opposing to said second side, said leadframe having a plurality of leads, each said lead having an internal lead wrapped inside a molding compound packaging said memory chip and an external lead exposed outside said molding compound; wherein
among said plurality of leads, said external leads of at least a pair of V_{DD} leads are arranged along said first and third sides, respectively; said internal leads of said pair of V_{DD} leads are connected to form a first linear segment perpendicular to said first and third sides; said first linear segment is neighboring and parallel to said second side;
among said plurality of leads, said external leads of at least a pair of V_{SS} leads are arranged along said first and third sides, respectively; said internal leads of said pair of V_{SS} leads are connected to form a second linear segment perpendicular to said first and third sides; said second linear segment is neighboring and parallel to said fourth side;
said external leads of the other leads of said leadframe are arranged along at least said second and fourth sides; and
said internal leads of the other leads of said leadframe are positioned between said first linear segment and said second side, and between said second linear segment and said fourth side.

2. The chip-scale packaging leadframe according to claim 1, wherein said external lead of one of said the other leads is positioned along the rim of said leadframe between said pair of V_{DD} leads and said second side.

3. The chip-scale packaging leadframe according to claim 1, wherein said external lead of one of said the other leads is positioned along the rim of said leadframe between said pair of V_{SS} leads and said fourth side.

4. The chip-scale packaging leadframe according to claim 1, wherein the gap between said external lead of one of said pair of V_{DD} leads and an adjacent said external lead is at least two times of the gap between two adjacent said external leads of said the other leads.

5. The chip-scale packaging leadframe according to claim 1, wherein the gap between said external lead of one of said pair of V_{SS} leads and an adjacent said external lead is at least two times of the gap between two adjacent said external leads of said the other leads.

6. The chip-scale packaging leadframe according to claim 1, wherein the gap between said external lead of one of said pair of V_{DD} leads and an adjacent said external lead is at least 1.0 mm.

7. The chip-scale packaging leadframe according to claim 1, wherein the gap between said external lead of one of said pair of V_{SS} leads and an adjacent said external lead is at least 1.0 mm.

8. The chip-scale packaging leadframe according to claim 1, wherein the area of said external lead of one of said pair of V_{DD} leads is at least 1.8 times of the area of said external leads of said the other leads.

9. The chip-scale packaging leadframe according to claim 1, wherein the area of said external lead of one of said pair of V_{SS} leads is at least 1.8 times of the area of said external leads of said the other leads.

10. The chip-scale packaging leadframe according to claim 1, wherein the dimension of said external lead of one of said pair of V_{DD} leads is at least 0.4×1.15 mm.

11. The chip-scale packaging leadframe according to claim 1, wherein the dimension of said external lead of one of said pair of V_{SS} leads is at least 0.4×1.15 mm.

12. The chip-scale packaging leadframe according to claim 1, wherein said external lead of a third V_{DD} lead is positioned along said second side; and said internal lead of said third V_{DD} lead is connected to said first linear segment.

13. The chip-scale packaging leadframe according to claim 12, wherein the pitch of said internal lead of said third V_{DD} lead is at least 2.5 times of the pitch of said internal leads of said the other leads of said leadframe.

14. The chip-scale packaging leadframe according to claim 1, wherein said external lead of a third V_{SS} lead is positioned along said fourth side; and said internal lead of said third V_{SS} lead is connected to said second linear segment.

15. The chip-scale packaging leadframe according to claim 14, wherein the pitch of said internal lead of said third V_{SS} lead is at least 2.5 times of the pitch of said internal leads of said the other leads of said leadframe.
